(19) United States
(12) Patent Application Publication
(10) Pub. No.: US 2024/0177286 A1
(43) Pub. Date: May 30, 2024

(54) MODELING FOR INDEXING AND SEMICONDUCTOR DEFECT IMAGE RETRIEVAL

(71) Applicant: APPLIED MATERIALS, INC., Santa Clara, CA (US)

(72) Inventors: Yuanhong Guo, Mountain View, CA (US); Sachin Dangayach, San Jose, CA (US); Rahul Reddy Komatireddi, Hyderabad (IN); Tianyuan Wu, San Jose, CA (US)

(21) Appl. No.: 18/070,744

(22) Filed: Nov. 29, 2022

(51) Int. Cl. G06T 7/00; G01N 21/95

(52) U.S. Cl. CPC G06T 7/0004; G01N 21/9501; G06T 2207/30148

(57) ABSTRACT

The subject matter of this specification can be implemented in, among other things, methods, systems, computer-readable storage medium. A method can include a processing device storing a plurality of feature vectors representative of previously processed image frames that correspond to various substrate processing defects. The method further includes receiving first image data comprising one or more image frames indicative of a first substrate processing defect. The method further includes determining a first feature vector corresponding to the first image data. The method further includes determining a selection of the plurality of feature vectors based on a proximity between the first feature vector and each of the selection of the plurality of feature vectors. The method further includes determining second image data comprising one or more image frames corresponding to the selection of the plurality of embedding vectors and performing an action based on determining the second image data.

### TECHNICAL FIELD

Embodiments of the instant specification generally relates to modeling for semiconductor defect image indexing and retrieval. More specifically, the embodiments of the instant specification relates to image search on semiconductor defect images using a novel combination of Deep Learning and vector search techniques.

### BACKGROUND

In manufacturing, for example in semiconductor device fabrication, fab yield depends on the device quality which can be measured directly using metrology tools and indirectly by monitoring process equipment sensors. This information is collected at different times in the product manufacturing lifecycle. When a manufacturing engineer needs to identify a problem with a process tool or a resulting product, he or she has to go through a laborious and costly process of analyzing lots of data points (e.g. metrology data of many samples with various measured parameters). For example, when an engineer is notified of a potential problem with a product, the engineer has to review corresponding metrology data to find an alarming characteristic of the product. A common way of identifying metrology violations is using image analysis.

The semiconductor industry generates images for failure analysis between process steps from various tools identifying defect position, characterization, and classification stored in various databases. An obstacle to defect detection/classification is searching within the databases for indexed data that assist in characterizing substrate processing defects corresponding to image processing. Searching for defect information in conventional systems is often limited by text queries which can be |subjective|, manual, tedious, indirect, inefficient and limited by an evaluator's knowledge, background, |related experience and specific interest|.

### SUMMARY

A method, system, and computer readable media (CRM) facilitating modeling for semiconductor defect image indexing and retrieval. In some embodiments, a method, performed by a processing device, may include storing a plurality of feature vectors representative of previously processed image frames that correspond to various substrate processing defects. The method further includes receiving first image data comprising one or more image frames indicative of a first substrate processing defect. The method further includes determining a first feature vector corresponding to the first image data. The method further includes determining a selection of the plurality of feature vectors based on a proximity between the first feature vector and each of the selection of the plurality of feature vectors. The method further includes determining second image data comprising one or more image frames corresponding to the selection of the plurality of embedding vectors and performing an action based on determining the second image data.

In some embodiments, a method may include a processing device receiving a first image frame indicative of a substrate processing defect. The method further includes generating a second image frame by cropping a first region of the first image frame. The method further includes generating a third image frame by cropping a second region of the first image frame, wherein the first region comprises the second region. The method further includes using the second image frame as input to a first machine learning (ML) model. The method further includes obtaining one or more outputs of the first ML model, the one or more outputs indicating a first feature vector corresponding to the second image frame. The method further includes using the third image frame as input to a second ML model and obtaining one or more outputs of the second ML model indicating a second feature vector corresponding to the third image frame. The method further includes updating one or more parameters of at least one of the first ML model or the second ML model based on a comparison between the one or more outputs of the first ML model and the one or more outputs of the second ML model.

In some embodiments, a non-transitory machine-readable storage medium comprises instructions that, when executed by a processing device, cause the processing device to perform operations. The operations may include storing, in a data storage device, a plurality of feature vectors representative of previously processed image frames that correspond to various substrate processing defects. The operations may further include receiving first image data comprising one or more image frames indicative of a first substrate processing defect. The operations may further include determining a first feature vector corresponding to the first image data. The operations may further include determining a selection of the plurality of feature vectors based on a proximity between the first feature vector and each of the selection of the plurality of feature vectors. The operations may further include determining second image data comprising one or more image frames corresponding to the selection of the plurality of embedding vectors. The operations may further include performing an action based on determining the second image data.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a block diagram illustrating an example system architecture in which implementations of the disclosure may operate.

FIG. 2 is a block diagram illustrating a substrate defect image indexing and retrieval system in which implementations of the disclosure may operate.

FIG. 3 is a block diagram of a defect size determination system, according to aspects of the disclosure.

FIG. 4 is a block diagram illustrating a process for training machine learning model(s) to generate outputs, according to aspects of the disclosure.

FIG. 5 illustrates a model training workflow and a model application workflow for substrate defect image indexing and retrieval, according to aspects of the disclosure.

FIGS. 6A-B illustrates a model architecture for substrate defect image indexing and retrieval, according to aspects of the disclosure.

FIG. 7 depicts a flow diagram of one example method for a substrate defect image indexing and retrieval, in accordance with some implementations of the present disclosure.

FIG. 8 depicts a block diagram of an example computing device, operating in accordance with one or more aspects of the present disclosure.

### DETAILED DESCRIPTION

Embodiments described herein are related to semiconductor defect image indexing and retrieval. In manufacturing, for example in semiconductor device fabrication, product quality can be measured directly using metrology tools and indirectly by monitoring process equipment sensors. This information is collected at different times in the product manufacturing lifecycle. When a manufacturing engineer needs to identify a problem with a process tool or a resulting product, he or she has to go through a laborious and costly process of analyzing lots of data points (e.g. metrology data of many samples with various measured parameters). For example, when an engineer is notified of a potential problem with a product, the engineer has to review corresponding metrology data to find an alarming characteristic of the product. One form of metrology data that is analyzed is through the uses of substrate imaging, such as, for example through the use of an electron microscope (e.g., a scanning electron microscope).

The semiconductor industry generates images for failure analysis and troubleshooting between process steps from various tools identifying defect position, characterization, and classification stored in various databases. An obstacle to defect detection/classification is searching within the databases for indexed data that assist in characterizing substrate processing defects corresponding to image processing. Searching for defect information in conventional systems is often limited by text queries which can be subjective, manual, tedious, indirect, inefficient and limited by an evaluator's knowledge, background, related experience, and specific interest. Conventional systems further fail to process images with new or out-of-distribution (OOD) data and combinations of multiple defects. Conventional substrate defect analysis further falls short in providing flexibility for targeting specific areas of a substrate and selectively removing the effects of other defects that may interfere with classification of a certain defect.

Conventional defect classification algorithms often require learning of fabrication processes such as substrate device processing parameters. Images, such as microscopic images, of defects often require years of experience by an engineer to understand the symptoms (e.g., size, orientation, shape, texture, morphology, type of defect, etc.) within the image and determine based on the symptoms one or more abnormalities of a substrate processing procedure or substrate processing equipment such as, for example, where the defect came from, how the defect was caused (e.g., how the defect was generated or transported, etc.). Further, the challenge of identifying defects is further exacerbated when multiple defects overlap one another.

Aspects and implementations of the present disclosure address these and other shortcomings of existing technology by providing a framework capable of indexing and retrieving digital imagery of semiconductor-based particles on substrates based on content of the image and/or defect size with options to focus or ignore specific areas of the defect in addition to employing domain specific filter. The present disclosure leverages computer-learned modeling to determine representation of images and build up a repository of images and/or feature representation of the images. In some embodiments, the present disclosure provides a searching mechanism that uses image features extracted using computational modeling (e.g., a deep learning based Visual Transformer (ViT) model. In some embodiments, the present disclosure provides options to crop certain portions of an image and/or ignore (e.g., mask) certain portions of the image. In some embodiments, the present disclosure provides a module to extract and make available size information (e.g., magnification, image scaling, defect size, etc.) for identifying similar images and/or defects.

The proposed solution leverages learning models (e.g., ViTs) to extract good representations of the defect image. The proposed solution employs an index optimized for vector similarity search to retrieve similar images in a fast manner. The proposed solution effectively mitigates the difficulties in processing new data as the index and database may be updated with new data. The proposed solution provides faster and more focused results over conventional text-based solutions. Further, the image-based search solution is not limited by defect keywords, class labels, and/or other institutional knowledge needed in conventional systems. The proposed solution further is capable of performing a dynamic search where new information can be retrieved, processed, and indexed as well as provides the ability to deal with multiple defect in the same image. The proposed solution further provides improved image representation of the substrate defects, in addition to, providing the flexibility to target specific areas of the image (e.g., using cropping and/or masking features).

A method, system, and computer readable media (CRM) facilitating modeling for semiconductor defect image indexing and retrieval. In an example embodiment, a method, performed by a processing device, may include storing a plurality of feature vectors representative of previously processed image frames that correspond to various substrate processing defects. The method further includes receiving first image data comprising one or more image frames indicative of a first substrate processing defect. The method further includes determining a first feature vector corresponding to the first image data. The method further includes determining a selection of the plurality of feature vectors based on a proximity between the first feature vector and each of the selection of the plurality of feature vectors. The method further includes determining second image data comprising one or more image frames corresponding to the selection of the plurality of embedding vectors and performing an action based on determining the second image data.

In an example embodiment, a method may include a processing device receiving a first image frame indicative of a substrate processing defect. The method further includes generating a second image frame by cropping a first region of the first image frame. The method further includes generating a third image frame by cropping a second region of the first image frame, wherein the first region comprises the second region. The method further includes using the second image frame as input to a first machine (ML) model. The method further includes obtaining one or more outputs of the first ML model, the one or more outputs indicating a first feature vector corresponding to the second image frame. The method further includes using the third image frame as input to a second ML model and obtaining one or more outputs of the second ML model indicating a second feature vector corresponding to the third image frame. The method further includes updating one or more parameters of at least one of the first ML model or the second ML model based on a comparison between the one or more outputs of the first ML model and the one or more outputs of the second ML model.

In an example embodiment, a non-transitory machine-readable storage medium comprises instructions that, when executed by a processing device, cause the processing device to perform operations. The operations may include storing, in a data storage device, a plurality of feature vectors representative of previously processed image frames that correspond to various substrate processing defects. The operations may further include receiving first image data comprising one or more image frames indicative of a first substrate processing defect. The operations may further include determining a first feature vector corresponding to the first image data. The operations may further include determining a selection of the plurality of feature vectors based on a proximity between the first feature vector and each of the selection of the plurality of feature vectors. The operations may further include determining second image data comprising one or more image frames corresponding to the selection of the plurality of embedding vectors. The operations may further include performing an action based on determining the second image data.

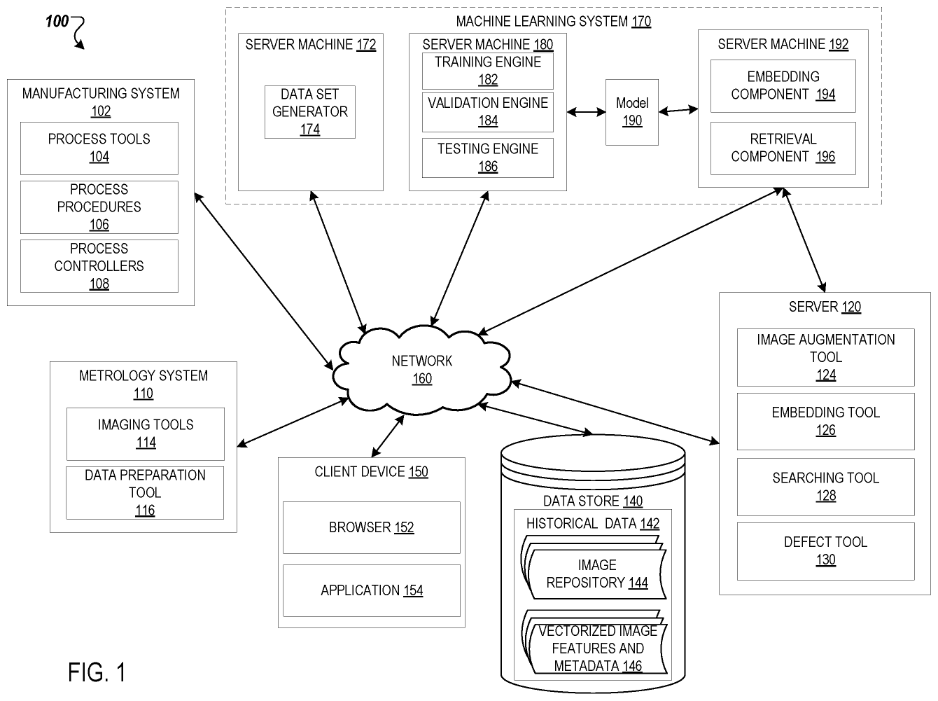

FIG. 1 is a block diagram illustrating an example system architecture 100 in which implementations of the disclosure may operate. As shown in FIG. 1, system architecture 100 includes a manufacturing system 102, a metrology system 110, a client device 150, a data store 140, a server 120, and a machine learning system 170. The machine learning system 170 may be part of the server 120. In some embodiments, one or more components of the machine learning system 170 may be fully or partially integrated into client device 150. The manufacturing system 102, the metrology system 110, the client device 150, the data store 140, the server 120, and the machine learning system 170 can each be hosted by one or more computing devices including server computers, desktop computers, laptop computers, tablet computers, notebook computers, personal digital assistants (PDAs), mobile communication devices, cell phones, hand-held computers, cloud servers, cloud-based system (e.g. cloud service device, cloud network device, or similar computing devices.

The manufacturing system 102, the metrology system 110, client device 150, data store 140, server 120, and machine learning system 170 may be coupled to each other via a network 160 (e.g., for performing methodology described herein). In some embodiments, network 160 is a private network that provides each element of system architecture 100 with access to each other and other privately available computing devices. Network 160 may include one or more wide area networks (WANs), local area networks (LANs), wired network (e.g., Ethernet network), wireless networks (e.g., an 802.11 network or a Wi-Fi network), cellular network (e.g., a Long Term Evolution (LTE) network), routers, hubs, switches, server computers, and/or any combination thereof. In some embodiments, network 160 is a cloud-based network capable of performing cloud-based functionality (e.g., providing cloud service functionality to one or more device in the system). Alternatively or additionally, any of the elements of the system architecture 100 can be integrated together or otherwise coupled without the use of network 160.

The client device 150 may be or include any personal computers (PCs), laptops, mobile phones, tablet computers, netbook computers, network connected televisions (“smart TV”), network-connected media players (e.g., Blue-ray player), a set-top-box, over-the-top (OOT) streaming devices, operator boxes, etc.. The client device may be capable of performing cloud based operations (e.g., with server 120, data store 140, manufacturing system 102, machine learning system 170, metrology system 110, etc.) The client device 150 may include a browser 152, an application 154, and/or other tools as described and performed by other systems of the system architecture 100. In some embodiments, the client device 150 may be capable of accessing the manufacturing system 102, the metrology system 110, the data store 140, server 120, and/or machine learning system 170 and communicating (e.g., transmitting and/or receiving) indications of metrology data, processed data (e.g., augmented image data, embedding vectors, and the like), process result data (e.g., critical dimension data, thickness data), and/or inputs and outputs of various process tools (e.g., imaging tools 114, data preparation tool 116, image augmentation tool 124, embedding tool 126, searching tool 128, defect tool 130, and/or retrieval component 194) at various stages processing of the system architecture 100, as described herein.

As shown in FIG. 1, manufacturing system 102 includes process tools 104, process procedures 106, and process controllers 108. A process controller 108 may coordinate operation of process tools 104 to perform on one or more process procedure 106. For example, various process tools may include specialized chambers such as etch chambers, deposition chambers (including chambers for atomic layer deposition, chemical vapor deposition, sputtering chamber, physical vapor deposition, or plasma enhanced versions thereof), anneal chambers, implant chambers, plating chambers, treatment chambers, and/or the like. In another example, machines may incorporate sample transportation systems (e.g., a selective compliance assembly robot arm (SCARA) robot, transfer chambers, front opening pods (FOUPs), side storage pod (SSP), and/or the like) to transport a sample between machines and process steps.

Process procedures 106, or sometimes referred to as process recipes or process steps, may include various specifications for carrying out operations by the process tools 104. For example, a process procedure 106 may include process specifications such as duration of activation of a process operation, the process tool used for the operation, the temperature, flow, pressure, etc. of a machine (e.g., a chamber), order of deposition, and the like. In another example, process procedures may include transferring instructions for transporting a sample to a further process step or to be measured by metrology system 110.

Process controllers 108 can include devices designed to manage and coordinate the actions of process tools 104. In some embodiments, process controllers 108 are associated with a process recipe or series of process procedures 106 instructions that when applied in a designed manner result in a desired process result of a substrate process. For example, a process recipe may be associated with processing a substrate to produce a target process results (e.g., critical dimension, thickness, uniformity criteria, etc.)

As shown in FIG. 1, metrology system 110 includes imaging tools 114 and data preparation tool 116. Imaging tools 114 can include a variety of sensors to measure process results (e.g., critical dimension, thickness, uniformity, etc.) within the manufacturing system 102. For example, the imaging tools 114 may include a scanning tunneling microscope (STM) or a scanning electron microscope (SEM). In another example, wafers processed within one or more processing chamber can be used to measure a critical dimension. Imaging tools 114 may also include devices to measure process results of substrate processed using the manufacturing system. For example, process results such as critical dimensions, thickness measurements (e.g., film layers from etches, depositing, etc.) can be evaluated of substrates processed according to process recipe and/or action performed by process controllers 108. Those measurement can also be used to measure conditions of a chamber throughout a substrate process procedure.

Data preparation tool 116 may include process methodology to extract features and/or generate synthetic/engineered data associated with data measured by imaging tools 114. In some embodiments, data preparation tool 116 can identify correlations, patterns, and/or abnormalities of metrology or process performance data. For example, data preparation tool 116 may perform a feature extraction where data preparation tool 116 uses combinations of measured data to determine whether a criterion is satisfied. For example, data preparation tool 116 can analyze multiple data points of an associated parameter to determine whether rapid changes occurred during a substrate process procedure across multiple processing chambers. In some embodiments, data preparation tool 116 performing a normalization across the various sensor data associated with various process chamber conditions. A normalization may include processing the incoming sensor data to appear similar across the various chambers and sensors used to acquire the data.

In some embodiments, data preparation tool 116 can perform one or more of a process control analysis, univariate limit violation analysis, or a multivariate limit violation analysis on metrology data (e.g., obtained by imaging tools 114). For example, data preparation tool 116 can perform statistical process control (SPC) by employing statistics based methodology to monitor and control process controllers 108. For example, SPC can promote efficiency and accuracy of a substrate processing procedure (e.g., by identifying data points that fall within and/or outside control limits).

In some embodiments, the extracted features, generated synthetic/engineered data, and statistical analysis can be used in association with machine learning system 170 (e.g., to train, validate, and/or test machine learning model 190). Additionally and/or alternatively, data preparation tool 116 can output data to server 120 to be used by any of image augmentation tool 124, embedding tool 126, searching tool 128, and defect tool 130.

Data store 140 may be a memory (e.g., random access memory), a drive (e.g., a hard drive, a flash drive), a database system, cloud-based system, or another type of component or device capable of storing data. Data store 140 may store one or more historical data 142 including housing an image repository 144 of previously processed images (e.g., of substrate defects) and corresponding vectorized image features and metadata 146. The vectorized image data may include a feature vector or embeddings data that are representative of imaging data (e.g., image frames, images acquired using imaging tools 114).

Server 120 may include one or more computing devices such as a rackmount server, a router computer, a server computer, a personal computer, a mainframe computer, a laptop computer, a tablet computer, a desktop computer, etc. The server 120 can include an image augmentation tool 124, an embedding tool 126, a searching tool 128, and/or a defect tool 130. Server 120 includes a cloud server or a server capable of performing one or more cloud-based functions. For example, one or more of operations of image augmentation tool 124, imbedding tool 126, searching tool 128, and/or defect tool 130 may be provided to a remote device (e.g., client device 150) using a cloud environment.

The image augmentation tool 124 receives image data (e.g., image frames) indicating substrate processing defects and performs image augmentations on the received image data. In some embodiments, the image augmentation tool 124 performing a filtering procedure where processing logic processes a received selection of image frames and by identifying features of the images and removing image frames that do not fit particular criteria. For example, images of substrate defects may be included within a set of images that include graphs, data tables, and/or metrology-related images. The filtering procedure identifies which images depict the substrate defect and removes images that do not direct indicate the substrate processing defect.

In some embodiments, the image augmentation tool 124 performs a cropping procedure with one or more of the received image frames. Cropping is the removal of unwanted outer areas from a photographic or illustrated image. The process usually consists of the removal of some of the peripheral areas of an image to remove extraneous trash from the picture, to improve its framing, to change the aspect ratio, or to accentuate or isolate the subject matter from its background. This can be performed by using image editing software and/or algorithms simulating image editing procedures. For example, the image augmentation 124 may receive a selection of one or more image frames (e.g., from metrology system 110 and/or client device 150) and crop the one or more image frames according to the selection (e.g., generating second image frames based on cropping first image frames according to the selection).

In some embodiments, the image augmentation tool 124 performs a masking procedure with one or more of the received image frames. Image masking is a technique used to isolate different parts of an image. For examples, image masking may include photo-compositing multiple images, hiding all or part of applying selective adjustments, making cut-outs (e.g., removing backgrounds), adjust transparency, and/or the like. For example, the image augmentation 124 may receive a selection of one or more image frames (e.g., from metrology system 110 and/or client device 150) and mask the one or more image frames according to the selection (e.g., generating second image frames based on cropping first image frames according to the selection).

The embedding tool 126 receives image data including one or more image frames (e.g., from metrology system 110) and determining embedding data representative of the image data. The embedding tool 126 includes process methodology to extract features and/or generate synthetic/engineered data associated with data measured by imaging tools 114 in the form of feature data (e.g., feature vectors). In some embodiments, embedding tool 116 can identify correlations, patterns, and/or abnormalities of metrology or process performance data. An embedding is a relatively low-dimensional space into which a high-dimensional representation (e.g., images) can be translated into. The embedding data (e.g., features vectors) capture semantics of the received image frames. The embedding tool 126 outputs embedding data (e.g., for use by the searching tool 128). The output of the embedding layer can be further passed on to other machine learning techniques such as clustering, k nearest-neighbor analysis, etc.

The searching tool 128 receives embedding data (e.g., feature vectors, feature embeddings) and determines other feature embeddings (e.g., vectorized image features and metadata) corresponding to previously processed images (e.g., image repository). The searching tool 128 performs a proximity search between the received feature embeddings and one or more feature embeddings of the vectorized image and features and metadata 146 of historical data 142.

In some embodiments, the searching tool 128 determines a set of proximate images of the image repository 144 using vector search and/or nearest neighbor solution methodology. The searching tool may identify vectors that are closest (e.g., most similar to) a received and/or provided feature vector.

In some embodiments, the searching tool 128 scans the historical data 142 and fetches the image repository 144 and the vectorized image features and metadata 146. The searching tool 128 may employ and indexing of the vectorized images features to quickly parses feature vectors. In some embodiments, the searching tool leverage Euclidean distance and/or Cosine similarity to determine a distance between feature vectors.

The defect tool 130 receives one or more similar image frames indicating a substrate processing defect. The defect tool 130 identifies a substrate processing defect based on the selection of similar image frames. The defect tool 130 identifies an instance of abnormality of a fabrication process based on the comparison between a current image and each of the selection of similar image frames. In some embodiments, the defect tool 138 receives the similar from the pattern mapping tool 137 and identifies the instance of abnormality based on the sample pattern.

The defect tool 130 may retrieve failure mode and effect analysis (FMEA) data. The FMEA data may include a list of known issues and root causes for the given equipment that has known symptoms associated with each. The defect identified and/or similar images received by the defect tool 138 are applied to the list of known issues and a report is generated identifying common causes of the defect. For example, the defect tool 130 may determine a defect and identify a tool, machine, or operation of the fabrication process corresponding to the identified defect.

In some embodiments the defect tool 138 can be used with process dependency data to identify a tool, machine, or process that is operated upstream (e.g., an operation step that occurred prior to the current manufacturing step of the same fabrication process) from the current machine operation being performed on a current sample. For example, a current sample may have recently undergone a first operation by a first machine. In some embodiments, the defect tool 130 can leverage combination of the process dependency data and failure mode and effect analysis data to lookup past operations for a sample, such as a second operation by a second machine or tool.

Once the instance of abnormality is identified, the defect tool 130 can proceed by performing one of altering at least one of an operation of a machine or an implementation of a process associated with the instance of abnormality and/or providing a graphical user interface (GUI) presenting a visual indicator of a machine or process associated with the instance of abnormality. The GUI may be sent through network 160 and presented on client device 150. In some embodiments, altering the operation of the machine or the implementation of the process may include sending instructions to the manufacturing execution system 102 to alter process tools 104, process procedures 106, and/or process controllers 108.

As previously described, some embodiments of the image augmentation tool 124, embedding tool 126, searching tool 128, and/or defect tool 130 may perform their described methodology using a machine learning model. The associated machine learning models may be generated (e.g., trained, validated, and/or tested) using machine learning system 170. The following example description of machine learning system 170 will be described in the context using machine learning system 170 to generate a machine learning model 190 associated embedding tool 126. However, it should be noted that this description is purely example. Analogous processing hierarchy and methodology can be used in the generation and execution of machine learning models associated with the image augmentation tool 124, embedding tool 126, searching tool 128, and/or defect tool 130 may perform their described methodology using a machine learning model.

The machine learning system 170 may include one or more computing devices such as a rackmount server, a router computer, a server computer, a personal computer, a mainframe computer, a laptop computer, a tablet computer, a desktop computer a cloud computer, a cloud server, a system stored on one or more clouds, etc. The machine learning system 170 may include an embedding component 194 and a retrieval component 196. In some embodiments, the embedding component 194 may receive as input one or more image frames indicative of a substrate processing defect and use historical data 142 with a trained machine learning model 190 to determine a feature embedding corresponding to the image frames. In some embodiments, the retrieval component 196 may use a trained machine learning model 190 to search the image repository 144 using the vectorized image features and metadata 146.

In some embodiments, the machine learning system 170 further includes server machine 172 and server machine 180. The server machine 172 and 180 may be one or more computing devices (such as a rackmount server, a router computer, a server computer, a personal computer, a mainframe computer, a laptop computer, a tablet computer, a desktop computer, a cloud computer, a cloud server, a system stored on one or more clouds, etc.), data stores (e.g., hard disks, memories databases), networks, software components, or hardware components.

Server machine 172 may include a data set generator 174 that is capable of generating data sets (e.g., a set of data inputs and a set of target outputs) to train, validate, or test a machine learning model. The data set generator 174 may partition the historical data 142 into a training set (e.g., sixty percent of the historical data, or any other portion of the historical data), a validating set (e.g., twenty percent of the historical data, or some other portion of the historical data), and a testing set (e.g., twenty percent of the historical data). In some embodiments, the data set generator 174 generates multiple sets of training data. For example, one or more sets of training data may include each of the data sets (e.g., a training set, a validation set, and a testing set).

Server machine 180 includes a training engine 182, a validation engine 184, and a testing engine 186. The training engine 182 may be capable of training a machine learning model 190 using one or more images of image repository 144, vectorized image features and metadata 146, and/or historical process result data 148 of the historical data 142 (of the data store 140). In some embodiments, the machine learning model 190 may be trained using one or more outputs of the data preparation tool 116, the image augmentation tool 124, the embedding tool 126, searching tool 128, and/or defect tool 130. For example, the machine learning model 190 may be a hybrid machine learning model using image data and/or embedded features such as a feature extraction, mechanistic modeling and/or statistical modeling. The training engine 182 may generate multiple trained machine learning models 190, where each trained machine learning model 190 corresponds to a distinct set of features of each training set.

The validation engine 184 may determine an accuracy of each of the trained machine learning models 190 based on a corresponding set of features of each training set. The validation engine 184 may discard trained machine learning models 190 that have an accuracy that does not meet a threshold accuracy. The testing engine 186 may determine a trained machine learning model 190 that has the highest accuracy of all of the trained machine learning models based on the testing (and, optionally, validation) sets.

In some embodiments, the training data is provided to train the machine learning model 190 such the trained machine learning model may receive a new input having new image data indicative of a new substrate processing defect. The new output may indicate a new feature embedding (e.g., feature vector). In some embodiments, the training data may further be used such that the new output further includes a selection of similar feature vectors corresponding to images of similar substrate processing defects.

The machine learning model 190 may refer to the model that is created by the training engine 182 using a training set that includes data inputs and corresponding target output (image frames and corresponding vectorized image features and metadata). Patterns in the data sets can be found that map the data input to the target output (e.g. identifying connections between portions of the sensor data and resulting chamber status), and the machine learning model 190 is provided mappings that captures these patterns. The machine learning model 190 may use one or more of logistic regression, syntax analysis, decision tree, or support vector machine (SVM). The machine learning may be composed of a single level of linear of non-linear operations (e.g., SVM) and/or may be a neural network.

Embedding component 194 may provide current data (e.g., image frames indicating substrate processing defects) as input to trained machine learning model 190 and may run trained machine learning model 190 on the input to obtain one or more outputs including a set of vectorized image features and metadata. Embedding component 194 may be capable of identifying confidence data from the output that indicates a level of confidence of the predicted vectorized image features and metadata. In one non-limiting example, the level of confidence is a real number between 0 and 1 inclusive, where 0 indicates no confidence of the one or more chamber statuses and 1 represents absolute confidence in the chamber status.

For purpose of illustration, rather than limitation, aspects of the disclosure describe the training of a machine learning model and use of a trained learning model using information pertaining to historical data 142. In other implementations, a heuristic model or rule-based model is used to determine a chamber status.

In some embodiments, the functions of client devices 150, server 120, data store 140, and machine learning system 170 may be provided by a fewer number of machines than shown in FIG. 1. For example, in some embodiments server machines 172 and 180 may be integrated into a single machine, while in some other embodiments server machine 172, 180, and 192 may be integrated into a single machine. In some embodiments, the machine learning system 170 may be fully or partially provided by server 120.

In general, functions described in one embodiment as being performed by client device 150, data store 140, metrology system 110, manufacturing system 102, and machine learning system 170 can also be performed on server 120 in other embodiments, if appropriate. In addition, the functionality attributed to a particular component can be performed by different or multiple components operating together.

In embodiments, a “user” may be represented as a single individual. However, other embodiments of the disclosure encompass a “user” being an entity controlled by multiple users and/or an automated source. For example, a set of individual users federated as a group of administrators may be considered a “user.”

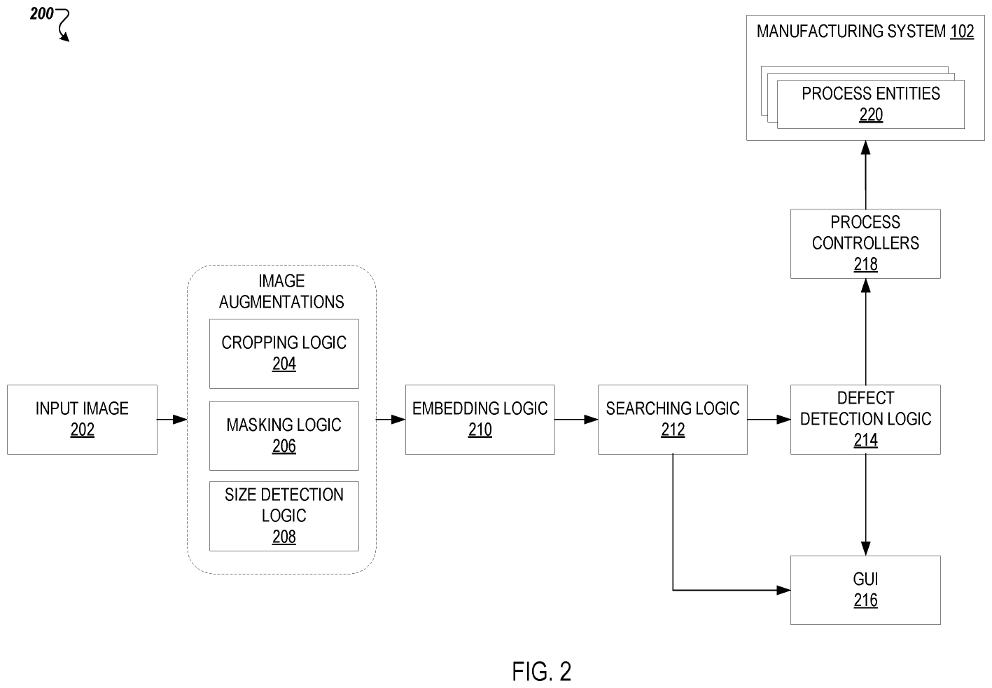

FIG. 2 is a block diagram illustrating a substrate defect image indexing and retrieval system 200 in which implementations of the disclosure may operate. The substrate defect image indexing and retrieval system 200 may include aspects and/or features of system architecture 100.

As shown in FIG. 2, the substrate defect indexing and retrieval system 200 receives an input image 202. The input image may include one or more image frames indicative of a substrate processing defect. The input image 202 may include an image of a substrate process result with a substrate processing defect. For example, the input image 202 may include scanning tunneling microscope (STM) or scanning electron microscope (SEM) images.

As shown in FIG. 2, the substrate defect indexing and retrieval system 200 includes an image augmentation logic including cropping logic 204, masking logic 206, and size detection logic 208. The cropping logic 204 performs a cropping procedure with one or more of the received image frames. Cropping is the removal of unwanted outer areas from a photographic or illustrated image. The process usually consists of the removal of some of the peripheral areas of an image to remove extraneous trash from the picture, to improve its framing, to change the aspect ratio, or to accentuate or isolate the subject matter from its background. This can be performed by using image editing software and/or algorithms simulating image editing procedures. For example, the cropping logic 204 may receive a selection of one or more image frames and crop the one or more image frames according to the selection (e.g., generating second image frames based on cropping first image frames according to the selection).

The masking logic 206 performs a masking procedure with one or more of the received image frames. Image masking is a technique used to isolate different parts of an image. For examples, image masking may include photo-compositing multiple images, hiding all or part of an image, applying selective adjustments, making cut-outs (e.g., removing backgrounds), adjust transparency, and/or the like. For example, masking logic 206 may receive a selection of one or more image frames and mask the one or more image frames according to the selection (e.g., generating second image frames based on cropping first image frames according to the selection).

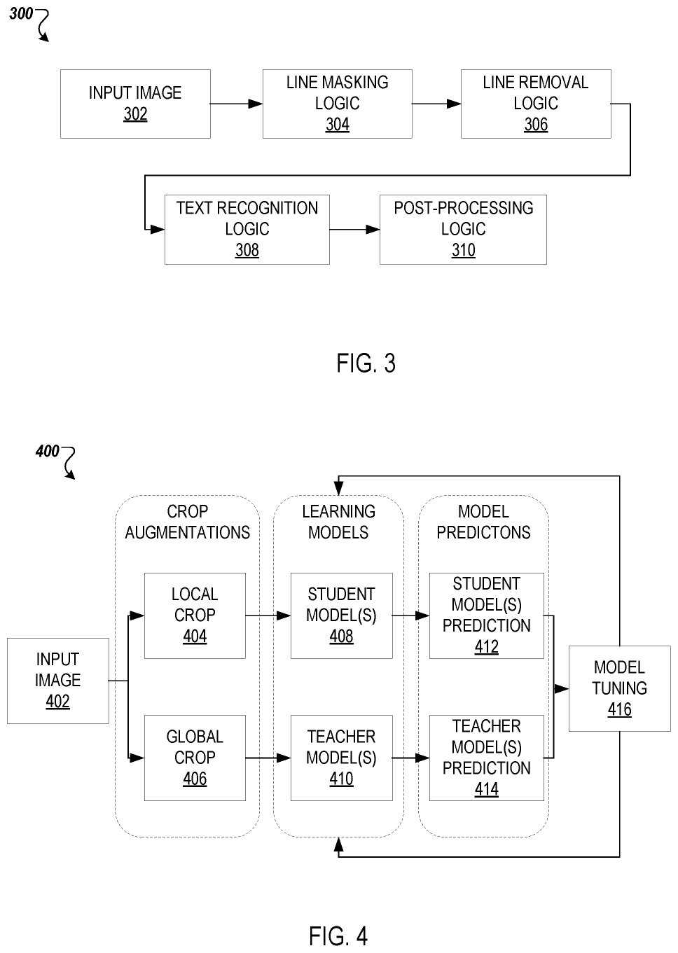

The size detection logic 208 processing the input image 202 and extracts content from the input image 202 indicating an image scaling factor associated with the input image 202. An image scaling factor indicates a relative size of the depiction within the image relative to the size of the image. For example the image scaling factor may include an image scale, a magnification factor, an indicated size of the object depicted, and the like. The size detection logic 208 extracts the size identifying information (e.g., text) and determines the size of the depicted defect. The size of the defect is further passed to one or more downstream processes (e.g., embedding logic 210, searching logic 212, defect detection logic 214, and the like). Further details regarding the size detection logic 208 is discussed in association with FIG. 3.

As shown in FIG. 2, the substrate defect indexing and retrieval system 200 includes embedding logic 210. The embedding logic 210 receives image data that includes the input image 202. The embedding logic 210 includes process methodology to extract features and/or generate synthetic/engineered data associated with data measured by imaging tools in the form of feature data (e.g., feature vectors). In some embodiments, embedding logic 210 can identify correlations, patterns, and/or abnormalities of metrology or process performance data. An embedding is a relatively low-dimensional space into which a high-dimensional representation (e.g., images) can be translated into. The embedding data (e.g., features vectors) capture semantics of the received image frames. The embedding logic 210 outputs embedding data (e.g., for use by the searching tool 128). The output of the embedding layer can be further passed on to other machine learning techniques such as clustering, k nearest-neighbor analysis, etc.

As shown in FIG. 2, the substrate defect indexing and retrieval system 200 includes searching logic 212. The searching logic 212 receives embedding data (e.g., feature vectors, feature embeddings) and determines other feature embeddings (e.g., vectorized image features and metadata) corresponding to previously processed images (e.g., image repository). The searching logic 212 performs a proximity search between the received feature embeddings and one or more feature embeddings of the vectorized image and features and metadata of previously processed images of other substrate processing defects.

In some embodiments, the searching logic 212 determines a set of proximate images of an image repository using vector search and/or nearest neighbor solution methodology. The searching tool may identify vectors that are closest to (e.g., most similar to) a received and/or provided feature vector.

In some embodiments, the searching logic 212 scans a data structure and fetches an image repository and corresponding vectorized image features and metadata. The searching logic 212 may employ indexing methodology of the vectorized images features to quickly parse feature vectors. In some embodiments, the searching tool leverage Euclidean distance and/or Cosine similarity to determine a distance between feature vectors.

As shown in FIG. 2, the substrate defect indexing and retrieval system 200 including defect detection logic 214. The defect detection logic 214 receives one or more similar image frames indicating a substrate processing defect. The defect detection logic 214 identifies a substrate processing defect based on the selection of similar image frames. The defect detection logic 214 identifies an instance of abnormality of a fabrication process based on the comparison between a current image and each of the selection of similar image frames. In some embodiments, the defect detection logic 214 receives the similar images from the searching logic 212 and identifies the instance of abnormality based on the similar images.

The defect detection logic 214 may retrieve failure mode and effect analysis (FMEA) data. The FMEA data may include a list of known issues and root causes for the given equipment that has known symptoms associated with each. The defect identified and/or similar images received by the defect detection logic 214 are applied to the list of known issues and a report is generated identifying common causes of the defect. For example, the defect detection tool 214 may determine a defect and identify a tool, machine, or operation of the fabrication process corresponding to the identified defect.

In some embodiments, the defect detection logic 214 can be used with process dependency data to identify a tool, machine, or process that is operated upstream (e.g., an operation step that occurred prior to the current manufacturing step of the same fabrication process) from the current machine operation being performed on a current sample. For example, a current sample may have recently undergone a first operation by a first machine. In some embodiments, the defect detection tool 214 can leverage combination of the process dependency data and failure mode and effect analysis data to lookup past operations for a sample, such as a second operation by a second machine or tool.

Once the instance of abnormality is identified, the defect tool 130 can proceed by performing one of altering at least one of an operation of a machine or an implementation of a process associated with the instance of abnormality and/or providing a graphical user interface (GUI) 216 presenting a visual indicator of a machine or process associated with the instance of abnormality. The GUI may be sent through network 160 and presented on client device 150. In some embodiments, altering the operation of the machine or the implementation of the process may include sending instructions to the manufacturing execution system 102 to alter process entities (e.g., process tools 104, process procedures 106, and/or process controllers 108 of FIG. 1) of manufacturing system 102.

In some embodiments, the searching logic 212 outputs a selection of similar vectorized image features or images with similar vectorized images features as the input image 202. The image may be sent to GUI 216 directly without determining the particular defect. For example, the GUI 216 may include a location to show the images that have been determined to be similar to input image 202.

FIG. 3 illustrates block diagram of a defect size determination system 300, according to aspects of the disclosure. One or more features discussed in associated with FIG. 3 may be carried out by size detection logic 208 of FIG. 2. As shown in FIG. 3, the defect size determination system 300 may include receiving an input image 302, line masking logic 304, line removal logic 306, text recognition logic 308, and/or post processing logic 310. The input image 302 may include one or more image frames indicative of a substrate processing defect. The input image 302 may include an image of a substrate process result with a substrate processing defect. For example, the input image 302 may include scanning tunneling microscope (STM) or scanning electron microscope (SEM) images.

The line masking logic 304 determines placement of edges within an image frame. The line masking logic may determine boundaries or global edges of the image frames. For example, some images may include a vertical line or a horizontal line on an edge of the image frame. In some embodiments the line masking logic 304 performs gamma corrected thresholding to identify one or more edge within the image frame. For example, a vertical and/or a horizontal line may be used within the image frame to identity data stored within the image such as, for example, text overlaid on the image. In some embodiments the line masking logic 304 performs localization using segmentation and generates a mask for inpainting of the image frames.

The line removal logic 306 receives line masking data from the line masking logic 304. The line removal tool applies image augmentation methodology (e.g., cropping, masking) portion of the image frame based on the detected lines. For example, an image may include a brand logo or other artificial mark that is identified using the line masking logic 304. The line removal logic 306 may apply a mask to remove lines detected by the line masking logic 304.

The text recognition logic 308 identifies text within an image frame. For example, an image may include a relative image scaling factor such as a scale indicating distances represented on the image. The text recognition logic 308 may identify the number and units a given image scaling factor (e.g., magnification, relative depicted distances, etc.). The text recognition logic 308 may isolate the text from the remaining portion of the input image 302.

The post-processing logic 310 takes action based on the recognized text. For example, the post-processing log may perform data cleaning and standardization. This may include providing a clean depicting of the region of the input image 302 identified by the text recognition logic 308. The post-processing logic 310 may further include making the size data available to other processes of the system. In some embodiments, the post-processing logic 310 determine a size of the defect based on the scaling and provides the size of the defect (e.g., as metadata) to further embedding and/or classification procedures relating to the input image 302.

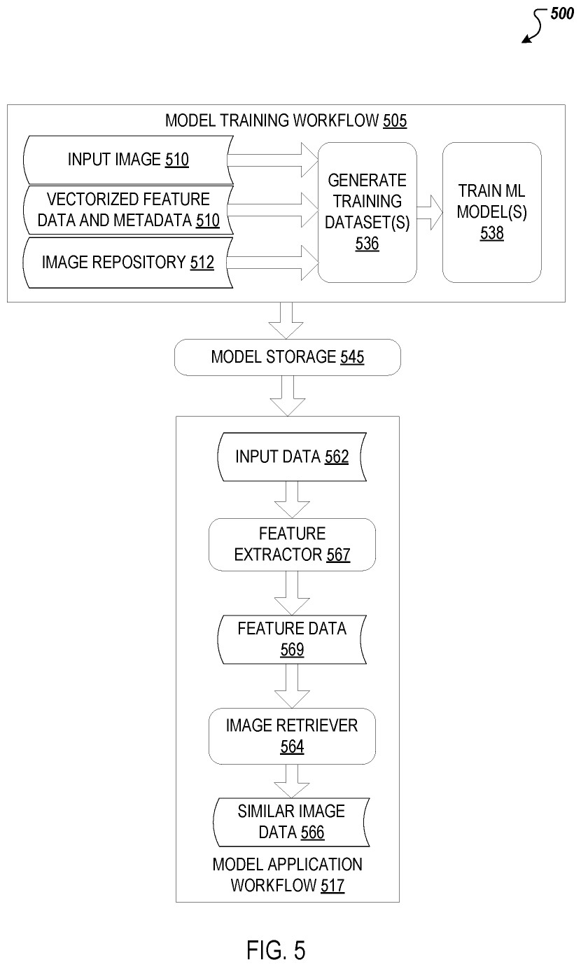

FIG. 4 is a block diagram illustrating a process 400 for training machine learning model(s) to generate outputs, according to certain embodiments. Process 400 includes receiving training data in the form of an input image 402. The input image 402 may include one or more image frames indicative of a substrate processing defect. The input image 402 may include an image of a substrate process result with a substrate processing defect. For example, the input image 402 may include scanning tunneling microscope (STM) or scanning electron microscope (SEM) images.

As shown in FIG. 4, process 400 includes crop augmentations of the input image 402. Copies of input image 402 may undergo a local crop 404 and copies of the input image 402 may undergo a global crop 406. A local crop may be associated with a selection of the input image 402 that is disposed within a selection of the input image 402. The local cropped images are used as input to student model(s) 408. The global cropped images are used as input to the teacher model(s) 410. The student model outputs student model(s) predictions 412. The student model predictions 412 and/or teacher model predictions 414 include a profile (e.g., distribution) indicating different embedding vectors corresponding to the input image 402 and corresponding levels of confidence (e.g., probabilities) associated with each of the outputs.

In operation, an example training procedure may include processing logic receiving a first image frame (e.g., input image 402) indicative of a substrate processing defect. Processing logic further generates a second image frame by cropping (e.g., global crop 406) a first region of the first image frame. Processing logic further generates a third image frame by cropping (e.g., local crop 404) a second region of the first image frame. The first region (associated with global crop 406) comprises the second region (associated with local crop 404). Processing logic uses the second image frame as input to a first machine (ML) model (e.g., teacher model(s) 410). Processing logic obtains one or more outputs of the first ML model. The one or more outputs (teacher model(s) prediction 414) indicate a first feature vector corresponding to the second image frame. Processing logic uses the third image frame as input to a second ML model (e.g., student model(s) 408). Processing logic obtains one or more outputs (e.g., student model(s) prediction 412) of the second ML model. The one or more outputs indicating a second feature vector corresponding to the third image frame. Processing logic updates (e.g., model tuning 416) one or more parameters of at least one of the first ML model or the second ML model based on a comparison between the one or more outputs of the first ML model and the one or more outputs of the second ML model.

In some embodiments, the student model(s) 408 may be a machine learning model that is similar to the trained teacher model(s) 410, but that contains fewer layers and/or nodes than each of the trained teacher model(s) 410, resulting in a more compressed machine learning model. In some embodiments, multiple student models 408 may be trained, where each student model 408 may be trained to predict embedding vectors for different subset of input images 402 in a cluster of input images that a teacher model 410 is trained to output error predictions for. In some embodiments, different student models 408 may be trained for each cluster of input images 402 and/or substrate processing defects. Each of the teacher models may then be used to train multiple student models.

In some embodiments, model tuning 416 includes determining an error or results of a loss function, such as, for example a ranking loss that is back-propagated to the student model(s) 408. The ranking loss represents a difference between the probability (from the student model) of the error and the probability (from the teaching model) of the perceived truth. For example, if the teacher model 410 determines a first prediction to have a first probability and the student model 408 determines the first prediction to have a second probability, the error is related to the difference between the two probabilities. In some embodiments, the ranking loss function may be a categorical cross entropy function, a Kullback-Leibler divergence function, or any suitable loss function.

In some embodiments, training may be performed by inputting input images 402 into the machine learning models one at a time. In some embodiments, after one or more rounds of training, processing logic may determine whether a stopping criterion has been met. A stopping criterion may be a target level of accuracy, a target number of processed images from the training dataset, a target amount of change to parameters over one or more previous data points, a combination thereof and/or other criteria. In one embodiment, the stopping criteria is met when at least a minimum number of data points have been processed and loss values have stabilized and/or stopped decreasing. Loss values may represent a summation of errors in the machine learning model. For example, loss values may represent a summation of deltas between a modeled value and an actual value. In one embodiment, the stopping criterion is met if accuracy of the machine learning model has stopped improving. If the stopping criterion has not been met, further training is performed. If the stopping criterion has been met, training may be complete. Once the machine learning model is trained, a reserved portion of the training dataset may be used to test the model.

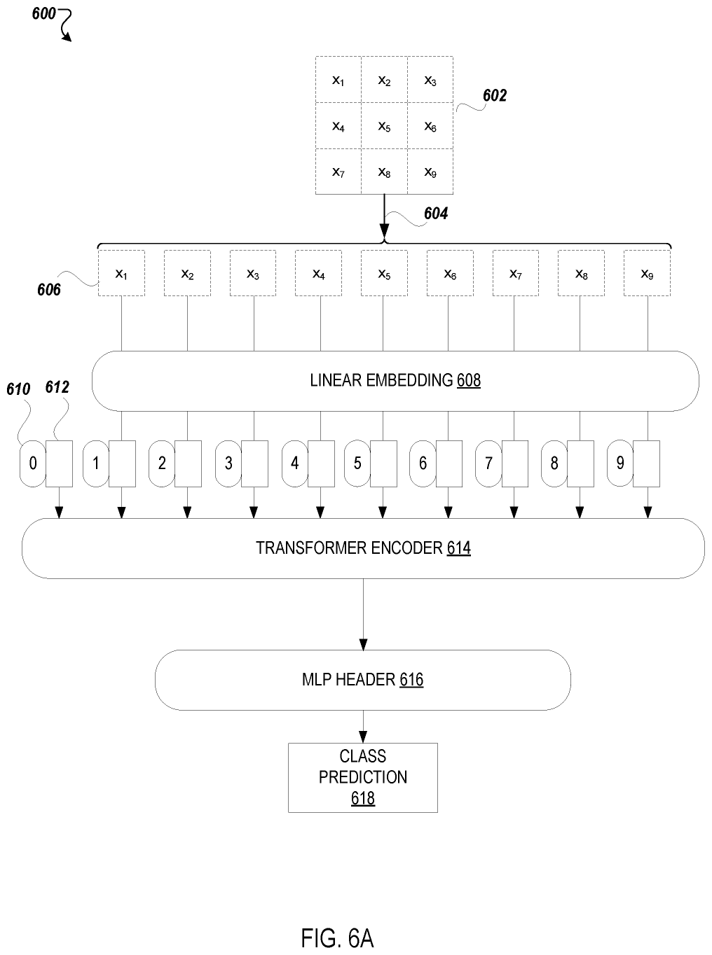

FIG. 5 illustrates a model training workflow 505 and a model application workflow 517 for substrate process result prediction, according to aspects of the disclosure. In some embodiments, the model training workflow 505 may be performed at a server which may or may not include a process defect image indexing and retrieval application, and the trained models are provided to a process defect image indexing and retrieval application, which may perform the model application workflow 517. The model training workflow 505 and the model application workflow 517 may be performed by processing logic executed by a processor of a computing device (e.g., server 120 of FIG. 1). One or more of these workflows 505, 517 may be implemented, for example, by one or more machine learning modules implemented processing device and/or other software and/or firmware executing on a processing device.

The model training workflow 505 is to train one or more machine learning models (e.g., regression models, boosted regression models, principle component analysis models, deep learning models, vision transformers) to perform one or more determining, predicting, modifying, etc. tasks associated with a process result predictor (e.g., feature extraction, image retrieval). The model application workflow 517 is to apply the one or more trained machine learning models to perform the determining and/or tuning, etc. tasks for image data (e.g., image frames indicating substrate processing defects). One or more of the machine learning models may receive image data (e.g., image frames indicating substrate processing defects).

Various machine learning outputs are described herein. Particular numbers and arrangements of machine learning models are described and shown. However, it should be understood that the number and type of machine learning models that are used and the arrangement of such machine learning models can be modified to achieve the same or similar end results. Accordingly, the arrangements of machine learning models that are described and shown are merely examples and should not be construed as limiting

In some embodiments, one or more machine learning models are trained to perform one or more of the below tasks. Each task may be performed by a separate machine learning model. Alternatively, a single machine learning model may perform each of the tasks or a subset of the tasks. Additionally, or alternatively, different machine learning models may be trained to perform different combinations of the tasks. In an example, one or a few machine learning models may be trained, where the trained machine learning (ML) model is a single shared neural network that has multiple shared layers and multiple higher level distinct output layers, where each of the output layers outputs a different prediction, classification, identification, etc. The tasks that the one or more trained machine learning models may be trained to perform are as follows:
a. Feature Extractor 567—As discussed previously, the feature extractor receive image data (e.g., raw and/or augmented image frames indicative of a substrate processing defect). The feature extractor includes process methodology to extract features and/or generate synthetic/engineered data associated with data measured by imaging tools in the form of feature data (e.g., feature vectors). In some embodiments, the feature extractor can identify correlations, patterns, and/or abnormalities of metrology or process performance data. An embedding is a relatively low-dimensional space into which a high-dimensional representation (e.g., images) can be translated into. The embedding data (e.g., features vectors) capture semantics of the received image frames.
b. Image Retriever 564—The image retriever receives embedding data (e.g., feature vectors, feature embeddings) and determines other feature embeddings (e.g., vectorized image features and metadata) corresponding to previously processed images (e.g., image repository). The image retriever performs a proximity search between the received feature embeddings and one or more feature embeddings of the vectorized image and features and metadata. In some embodiments, the image retriever determines a set of proximate images (e.g., within a threshold proximity) using vector search and/or nearest neighbor solution methodology. In some embodiments, the image retriever leverages Euclidean distance and/or Cosine similarity to determine a distance between feature vectors.

To effectuate training, processing logic inputs the training dataset(s) 536 into one or more untrained machine learning models. (See FIG. 4 for further details on training) Prior to inputting a first input into a machine learning model, the machine learning model may be initialized. Processing logic trains the untrained machine learning model(s) based on the training dataset(s) to generate one or more trained machine learning models that perform various operations as set forth above.

Once one or more trained machine learning models 538 are generated, they may be stored in model storage 545, and may be added to a process defect image indexing and retrieval application. The process defect image indexing and retrieval application may then use the one or more trained ML models 538 as well as additional processing logic to implement an automatic mode, in which user manual input of information is minimized or even eliminated in some instances.

For model application workflow 517, according to one embodiment, input data 562 (e.g., image frames indicating a substrate processing defect) may be used as input to feature extractor 567, which may include a trained machine learning model. Based on the input data 562, feature extractor 567 outputs feature data 569 and metadata representative of the input data 562. The feature data 569 is input to image retriever 564, which may include a trained machine learning model. Based on the feature data 569, the image retriever 564 identifies one or more other images (e.g., similar image data 566) identified as similar to the input data 562 through the feature data 569

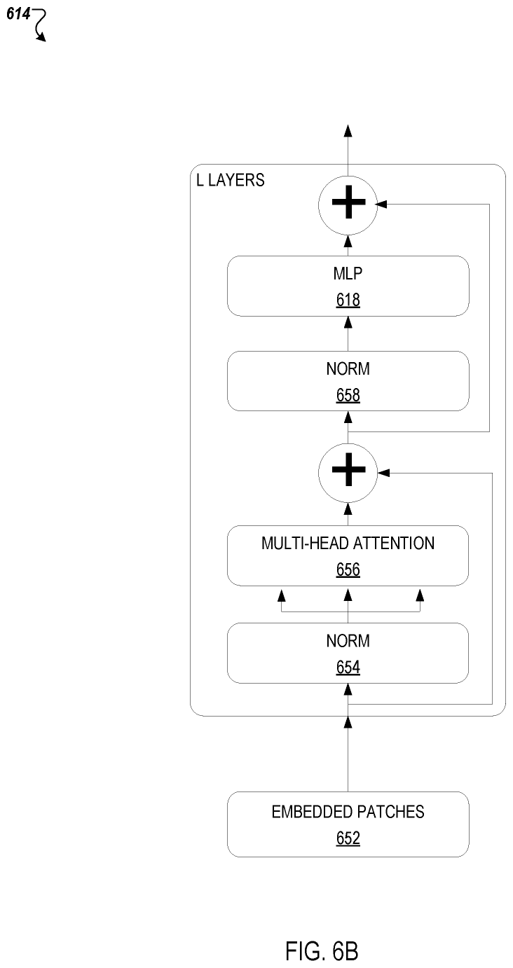

FIGS. 6A-B illustrates a model architecture 600 for substrate defect image indexing and retrieval, according to aspects of the disclosure. One or more ML models may be carried out using model architecture 600. In general, the model architecture 600 is composed of an embedding layer 608, an encoder 614, and a final head classifier 616. Initially, an image is subdivided into non-overlapping patches. Each patch is viewed by the architecture as an individual token. For an image of size c×h×w (where h is the height, w is the width and c represents the number of channel). Patches are extracted each of dimension×p×p. This forms a sequence of patches (x₁, x₂, . . . , xₙ) of length n, with

$$n = \frac{h w}{{p}^{2}} .$$

In some embodiments, the patch size p is chosen as 16×16 or 32×32.

As shown in FIG. 6A, at 604 an input image 602 is divided (e.g., flattened) into individual image patches. For example, the input image 602 is divided into a fixed number of equally sized patches or embedding tokens. The input image may be converted (e.g., flattened) into a sequence 606 of token embedding indicating content of image patches. In some embodiments, the model architecture uses constant latent vector size n through all of its layers and the patches are flattened and mapped to n dimensions with a trainable linear projection using linear embedding layer 608.

Before feeding the sequence of patches into the encoder 614, it is linearly projected into a vector of the model dimension d using a learned embedding matrix. The embedded representations are then concatenated together along with a learnable classification token that is used to perform the classification task. The embedded image patches are viewed by the Transformer as a set of patches without any notion of their order. To keep the spatial arrangement of the patches as in the original image, the positional information 610 is encoded and appended to the patch representations 612 (e.g., linear embedding representative of a content of a corresponding image patch). The resulting embedded sequence of patches with the token 0 is given by:

z₀=[v_{class};x₁E;x₂E; . . . ;xₙE]+Eₚₒₛ,EϵR^{(p}^{²}^{c)×d},EₚₒₛϵR^{(n+1)×d}

The resulting sequence of embedded patches z₀ is passed to the Transformer encoder 614. As shown in FIG. 6B, the encoder 614 is composed of L identical layers. Each one has two main subcomponents: (1) a multihead self-attention block (MSA) 656, and (2) a fully connected feed-forward dense block (MLP) 660. Each of the two subcomponents of the encoder employs residual skip connections and is preceded by a normalization layer (LN) (e.g., normalization layer 654 and normalization layer 658). At the last layer of the encoder 614, we take the first element in the sequence and pass it to an external head classifier for predicting the class label represented by y=LN(z_{L}⁰).

The MSA block 656 in the encoder 614 is the central component of the Transformer. The MSA block 656 determines the relative importance of a single patch embedding with respect to the other embeddings in the sequence. This block has four layers: the linear layer, the self attention layer, the concatenation layer, which concatenates the outputs of the multiple attention heads, and a final linear layer. At a high level, attention can be represented by attention weight, which is computed by finding the weighted sum over all values of the sequence z. The MSA block employs an attention function that maps a query and a set of key-value pairs to an outputs, where the query, keys, values, and output are all vectors. The output is computed as a weighted sum of values, where the weight assigned to each value is computed by a compatibility function of the query with the corresponding key. The results of all of the attention heads are concatenated together and then projected through a feed-forward layer with learnable weights to the desired dimension. The MLP 616 makes a class prediction 618 based on the received data from the encoder 614.

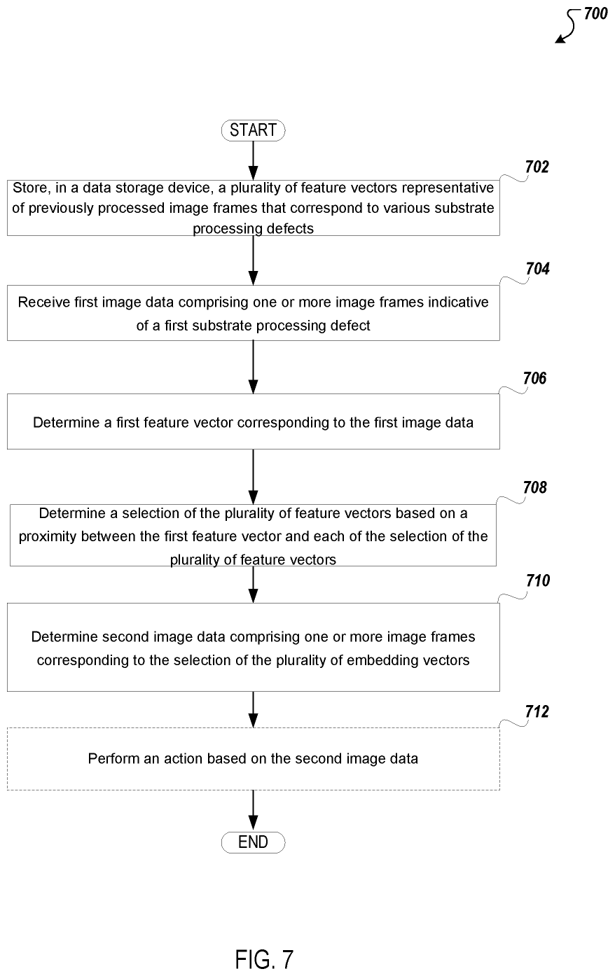

FIG. 7 depicts a flow diagram of one example method 700 for a substrate defect image indexing and retrieval, in accordance with some implementations of the present disclosure. Method 700 is performed by processing logic that may comprise hardware (e.g., circuitry, dedicated logic, etc.), software (such as is run on a general purpose computer system or a dedicated machine) or any combination thereof. In one implementation, the method is performed using server 120 and the trained machine learning model 190 of FIG. 1, while in some other implementations, one or more blocks of FIG. 7 may be performed by one or more other machines not depicted in the figures.

Method 700 may include receiving image data (e.g., associated with a substrate processing defect) and processing the received image data using a trained machine learning model 190. The trained model may be configured to generate, based on the image data a feature embedding of the image. Method 700 further identifies similar images that may illustrate similar defects.

At block 702, processing logic stores, in a data storage device, a plurality of feature vectors representative of previously processed image frames that correspond to various substrate processing defects. At block 704, processing logic receives first image data comprising one or more image frames indicative of a first substrate processing defect. The first image data may include one or more image frames indicative of a substrate processing defect. The input image may include an image of a substrate process result with a substrate processing defect. For example, the input image may include scanning tunneling microscope (STM) or scanning electron microscope (SEM) images.

In some embodiments, processing logic receives a first selection of a first image frame of the first image data and generates a second image frame by cropping a region of the first image frame based on the first selection. The first feature vector is determined using the second image frame. In some embodiments, processing logic receives a first selection of a first image frame of the first image data. Processing logic generates a second image frame by masking a region of the first image frame based on the first selection. The first feature vector is determined using the second image frame.

In some embodiments, processing logic extracts a selection of text from a first image frame of the first image data. Processing logic further determines an image scaling factor associated with the first image frame. Processing logic further determines, based on the image scaling factor, a size associated with the first substrate processing defect. The selection of the plurality of feature vectors is determined using the size.

At block 706, processing logic determines a first feature vector corresponding to the first image data. In some embodiments, processing logic further divides the first image frame of the first image data into a set of image patches corresponding to the first image frame. The processing logic further determines a set of linear embedding corresponding to a content of each image patch of the set of image patches. Processing logic further determines a set of positional embedding corresponding to a relative position of each of the image patches of the set of image patches. The first feature vector is determined based on the set of linear embedding and the set of positional embeddings.

At block 708, processing logic determines a selection of the plurality of feature vectors based on a proximity between the first feature vector and each of the selection of the plurality of feature vectors. At block 710, processing logic determines second image data comprising one or more image frames corresponding to the selection of the plurality of embedding vectors. Processing logic receives embedding data (e.g., feature vectors, feature embeddings) and determines other feature embeddings (e.g., vectorized image features and metadata) corresponding to previously processed images (e.g., image repository). Processing logic performs a proximity search between the received feature embeddings and one or more feature embeddings of the vectorized image and features and metadata. In some embodiments, processing logic determines a set of proximate images (e.g., within a threshold proximity) using vector search and/or nearest neighbor solution methodology. In some embodiments, processing logic leverages Euclidean distance and/or Cosine similarity to determine a distance between feature vectors.

At block 712, processing logic, optionally, performs an action based on determining the second image data. In some embodiments, processing logic optionally, prepares the second image data for presentation on a graphical user interface (GUI). For example, the second image data a set of image frames similar to the first image frame and indicate similar substrate processing defects. In another example, the second image data may be displayed on a GUI by displaying an indication of the first substrate processing defect.

In some embodiments, processing logic optionally, alters an operation of the process chamber and/or processing tool based on the second image data. For example, processing logic may determine a substrate processing defect based on the second image data. Processing logic further determines an instance of abnormality of a fabrication process associated with the first substrate processing defect. Processing logic may further transmit instructions (e.g., performance of a corrective action associated with fabrication process equipment) to one or more process controllers to alter one or more operations of a processing device associated with the instance of abnormality (e.g., alter a process recipe and/or process parameter, end substrate process of one or more process tools and/or process chambers, initiate preventive maintenance associated with one or more process chambers and/or process tools, etc.).

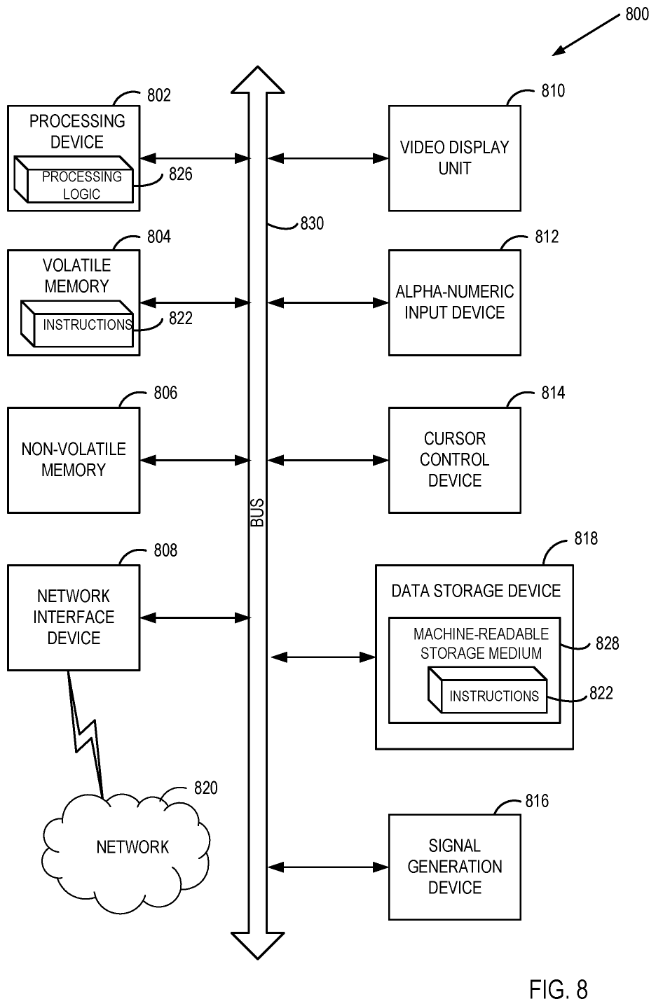

FIG. 8 depicts a block diagram of an example computing device 800, operating in accordance with one or more aspects of the present disclosure. In various illustrative examples, various components of the computing device 800 may represent various components of the client device 150, metrology system 110, server, 120, data store 140, and machine learning system 170, illustrated in FIG. 1.

Example computing device 800 may be connected to other computer devices in a LAN, an intranet, an extranet, and/or the Internet. Computing device 800 may operate in the capacity of a server in a client-server network environment. Computing device 800 may be a personal computer (PC), a set-top box (STB), a server, a network router, switch or bridge, or any device capable of executing a set of instructions (sequential or otherwise) that specify actions to be taken by that device. Further, while only a single example computing device is illustrated, the term “computer” shall also be taken to include any collection of computers that individually or jointly execute a set (or multiple sets) of instructions to perform any one or more of the methods discussed herein.

Example computing device 800 may include a processing device 802 (also referred to as a processor or CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which may communicate with each other via a bus 830.

Processing device 802 represents one or more general-purpose processing devices such as a microprocessor, central processing unit, or the like. More particularly, processing device 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 802 may be configured to execute instructions implementing method 700 illustrated in FIG. 7.

Example computing device 800 may further comprise a network interface device 808, which may be communicatively coupled to a network 820. Example computing device 800 may further comprise a video display 810 (e.g., a liquid crystal display (LCD), a touch screen, or a cathode ray tube (CRT)), an alphanumeric input device 812 (e.g., a keyboard), a cursor control device 814 (e.g., a mouse), and an acoustic signal generation device 816 (e.g., a speaker).

Data storage device 818 may include a machine-readable storage medium (or, more specifically, a non-transitory machine-readable storage medium) 828 on which is stored one or more sets of executable instructions 822. In accordance with one or more aspects of the present disclosure, executable instructions 822 may comprise executable instructions associated with executing methods 700 illustrated in FIG. 7.

Executable instructions 822 may also reside, completely or at least partially, within main memory 804 and/or within processing device 802 during execution thereof by example computing device 800, main memory 804 and processing device 802 also constituting computer-readable storage media. Executable instructions 822 may further be transmitted or received over a network via network interface device 808.

While the computer-readable storage medium 828 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, compact disc read only memory (CD-ROMs), and magnetic-optical disks, read-only memories (ROMs), random access memories (RAMs), erasable programmable read-only memory (EPROMs), electrically erasable programmable read-only memory (EEPROMs), magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method, comprising:
storing, in a data storage device, a plurality of feature vectors representative of previously processed image frames that correspond to various substrate processing defects;
receiving, by a processing device, first image data comprising one or more image frames indicative of a first substrate processing defect;
determining, by the processing device, a first feature vector corresponding to the first image data;
determining, by the processing device, a selection of the plurality of feature vectors based on a proximity between the first feature vector and each of the selection of the plurality of feature vectors;
determining, by the processing device, second image data comprising one or more image frames corresponding to the selection of the plurality of embedding vectors;
performing, by the processing device, an action based on determining the second image data.

2. The method of claim 1, further comprising:
identifying, by the processing device, the first substrate processing defect based on the second image data, wherein the action is further based on an identity of the first substrate processing defect.

3. The method of claim 2, further comprising:
identifying, by the processing device, an instance of abnormality of a fabrication process associated with the first substrate processing defect; and
causing, by the processing device, performance of a corrective action associated with fabrication process equipment based on the instance of abnormality.

4. The method of claim 1, further comprising:
preparing, by the processing device, one or more image frames of the second image data for presentation on a graphical user interface (GUI).

5. The method of claim 1, further comprising:
receiving, by the processing device, a first selection of a first image frame of the first image data; and
generating, by the processing device, a second image frame by cropping a region of the first image frame based on the first selection, wherein the first feature vector is determined using the second image frame.

6. The method of claim 1, further comprising:
receiving, by the processing device, a first selection of a first image frame of the first image data; and
generating, by the processing device, a second image frame by masking a region of the first image frame based on the first selection, wherein the first feature vector is determined using the second image frame.

7. The method of claim 1, further comprising:
extracting, by the processing device, a selection of text from a first image frame of the first image data;
determining, by the processing device, an image scaling factor associated with the first image frame; and
determining, by the processing device based on the image scaling factor, a size associated with the first substrate processing defect; wherein the selection of the plurality of feature vectors is determined further using the size.

8. The method of claim 1, further comprising:
dividing, by the processing device, a first image frame of the first image data into a set of image patches corresponding to the first image frame;
determining, by the processing device, a set of linear embeddings corresponding to a content of each image patch of the set of image patches;
determining, by the processing device, a set of positional embeddings corresponding to a relative position of each of the image patches of the set of image patches, wherein the first feature vector is determined based on the set of linear embedding and the set of positional embeddings.

9. A method, comprising:
receiving, by a processing device, a first image frame indicative of a substrate processing defect;
generating, by the processing device, a second image frame by cropping a first region of the first image frame;
generating, by the processing device, a third image frame by cropping a second region of the first image frame, wherein the first region comprises the second region;
using the second image frame as input to a first machine learning (ML) model;
obtaining one or more outputs of the first ML model, the one or more outputs indicating a first feature vector corresponding to the second image frame;
using the third image frame as input to a second ML model;
obtaining one or more outputs of the second ML model, the one or more outputs indicating a second feature vector corresponding to the third image frame;
updating one or more parameters of at least one of the first ML model or the second ML model based on a comparison between the one or more outputs of the first ML model and the one or more outputs of the second ML model.

10. The method of claim 9, wherein:
the one or more outputs of the first ML model further indicate a level of confidence associated with the first feature vector; and
the one or more outputs of the second ML model further indicate a level of confidence associated with the second feature vector.

11. The method of claim 9, further comprising:
dividing, using the first ML model, the second image frame into a set of image patches corresponding to the second image frame;
determining, using the first ML model, a set of linear embeddings corresponding to a content of each image patch of the set of image patches;
determining, using the first ML model, a set of positional embeddings each corresponding to a position of a corresponding image patch of the set of image patches, wherein the first feature vector is determined based on the set of linear embedding and the set of positional embedding.

12. The method of claim 9, wherein:
the one or more outputs of the first ML model comprise (i) a first set of predictions and (ii) a first set of probabilities each corresponding to a prediction of the first set of predictions; and
the one or more outputs of the second ML model comprise (i) a second set of predictions and (ii) a second set of probabilities each corresponding to a prediction of the second set of predictions

13. The method of claim 9, wherein at least one of first ML model or the second ML model comprise a Vision Transformer (ViT).

14. A non-transitory machine-readable storage medium comprising instructions that, when executed by a processing device, cause the processing device to perform operations comprising:
store, in a data storage device, a plurality of feature vectors representative of previously processed image frames that correspond to various substrate processing defects;
receive first image data comprising one or more image frames indicative of a first substrate processing defect;
determine a first feature vector corresponding to the first image data;
determine a selection of the plurality of feature vectors based on a proximity between the first feature vector and each of the selection of the plurality of feature vectors;
determine second image data comprising one or more image frames corresponding to the selection of the plurality of embedding vectors;
perform an action based on determining the second image data.

15. The non-transitory machine-readable storage medium of claim 14, the operations further comprising:
identify the first substrate processing defect based on the second image data, wherein the action is further based on an identity of the first substrate processing defect.

16. The non-transitory machine-readable storage medium of claim 15, the operations further comprising:
identify an instance of abnormality of a fabrication process associated with the first substrate processing defect; and
cause performance of a corrective action associated with fabrication process equipment based on the instance of abnormality.

17. The non-transitory machine-readable storage medium of claim 14, the operations further comprising:
prepare one or more image frames of the second image data for presentation on a graphical user interface (GUI).

18. The non-transitory machine-readable storage medium of claim 14, the operations further comprising:
receive a first selection of a first image frame of the first image data; and
generate a second image frame by at least one of cropping or masking a region of the first image frame based on the first selection, wherein the first feature vector is determined using the second image frame.

19. The non-transitory machine-readable storage medium of claim 14, the operations further comprising:
extract a selection of text from a first image frame of the first image data;
determine an image scaling factor associated with the first image frame; and
determine, based on the image scaling factor, a size associated with the first substrate processing defect, wherein the selection of the plurality of feature vectors is determined further using the size.

20. The non-transitory machine-readable storage medium of claim 14, the operations further comprising:
divide a first image frame of the first image data into a set of image patches corresponding to the first image frame;
determine a set of linear embeddings corresponding to a content of each image patch of the set of image patches;
determine a set of positional embeddings corresponding to a position of each of the image patches of the set of image patches, wherein the first feature vector is determined based on the set of linear embedding and the set of positional embedding.
